(19) United States
(12) Patent Application Publication
(10) Pub. No.: US 2013/0343006 A1
(43) Pub. Date: Dec. 26, 2013

(54) ELECTRICAL MODULE FOR BEING RECEIVED BY AUTOMATIC PLACEMENT MACHINES BY MEANS OF GENERATING A VACUUM

(71) Applicants: Claus Reitlinger, Wolnzach (DE); Thomas Kerssebrock, Munich (DE); Thomas Klingl, Mettenheim (DE); Felix Hudlberger, Rattenkirchen (DE); Frank Rehme, Einhausen (DE); Michael Gerner, Bad Tolz (DE)

(72) Inventors: Claus Reitlinger, Wolnzach (DE); Thomas Kerssebrock, Munich (DE); Thomas Klingl, Mettenheim (DE); Felix Hudlberger, Rattenkirchen (DE); Frank Rehme, Einhausen (DE); Michael Gerner, Bad Tolz (DE)

(73) Assignee: EPCOS AG, Munich (DE)

(21) Appl. No.: 13/996,497

(22) PCT Filed: Dec. 9, 2011
(86) PCT No.: PCT/EP11/72347

§ 371 Date: Sep. 9, 2013

(30) Foreign Application Priority Data
Dec. 22, 2010 (DE) 102010055627.0

(51) Int. Cl. H05K 7/02

(52) U.S. Cl. CPC H05K 7/026
USPC 361/728; 29/592.1

(57) ABSTRACT

The invention relates to an electrical module (100) for being received by automatic placement machines by means of generating a vacuum, comprising a carrier substrate (10), at least one component (20, 21) disposed on the carrier substrate (10), and a cover element (30) disposed above the at least one component (20, 21). A fixing component (40) by which the cover element (30) is attached to the at least one component (21) is disposed between the cover element (30) and the at least one component (21). The cover element can be implemented as a dimensionally stable, flat film by means of which it is possible to suction the module by means of vacuum for a placement method, and to place said module at a position on a circuit board.

The invention relates to an electrical module which can be received and placed on a printed circuit board by an automatic placement machine by means of generating a vacuum. The invention also relates to a method for producing an electrical module which can be received and placed on a printed circuit board by an automatic placement machine by means of generating a vacuum.

A module comprises a large number of components which are interconnected for the purpose of realizing a large variety of functions. As a result of using such modules, it is no longer necessary to create a dedicated circuit design for all functions of an application. Instead, the module can be integrated in a complex circuit as a complete assembly.

By way of example, duplexer or filter banks can be realized with a module of this kind. Modules can be incorporated in a relatively large circuit complex, for example, by means of an SMD (Surface Mounted Device) technique. In the SMD technique, solder paste is provided at a point on a printed circuit board at which the module is soldered to the printed circuit board in a subsequent production process. The module is initially mounted on the solder material by way of its lower face. The contact areas of the module are contact-connected to the printed circuit board by heating and melting the solder paste.

Automatic placement machines are generally used in order to place the module at the points on the printed circuit board at which the solder paste is applied. Automatic placement machines of this type can suck up the module, for example using vacuum pipettes by which, for example, a vacuum is generated on a cover of the module, as a result of which the module is reliably held on the automatic placement machines. The module is moved to the desired point on the printed circuit board by the automatic placement machine and placed there by the vacuum being turned off.

The components which are applied on a carrier substrate, for example surface acoustic wave components, can be surrounded by an epoxide compound on the carrier substrate and are therefore encapsulated. As an alternative to this, a closed cover can be provided above the components of the module, said cover sealing off the module and therefore forming a closed housing around the components. A planar surface can be created on the upper face of the module by the epoxide compound or the cover. A vacuum can be generated on the planar upper face of the encapsulation compound or of the cover by an automatic placement machine. As a result, the modules can be received by the automatic placement machine, in order to be placed at a specified point on a printed circuit board.

Encapsulation of the components by means of an encapsulation compound (molding method) is a very complicated process. Mounting a cover above the components of a module requires an increased amount of space on the carrier substrate of the module. Encapsulation of components by an encapsulation compound or by mounting a cover element, which is closed at the edge, is desirable, in particular, for modules in which components, for example flip-chip components, or wire connections between the components have to be specially protected. In the case of enclosed components, for example in the case of surface acoustic wave components, protection of the components is not necessarily required. Encapsulation of the components by means of an encapsulation material therefore represents a complicated and often unnecessary process. Mounting a cover above components of a module which are already enclosed is likewise unnecessary and additionally requires an increased amount of space on the carrier substrate of the module.

It is desirable to provide an electrical module for being received by automatic vacuum-operated placement machines, wherein the module can be received by an automatic placement machine by means of generating a vacuum and placed on a printed circuit board in a simple and reliable manner. A further aim is to specify a method for producing an electrical module for being received by automatic vacuum-operated placement machines, wherein the module can be received by an automatic placement machine by means of generating a vacuum and placed on a printed circuit board in a simple and reliable manner.

An electrical module for being received by automatic placement machines by means of a vacuum comprises a carrier substrate, at least one component which is arranged on the carrier substrate, and a cover element which is arranged above the at least one component. A fixing component, by means of which the covering element is fastened to the at least one component, is arranged between the covering element and the at least one component.

The covering element can be designed to be very thin, for example with a thickness of between 10 μm and 150 μm. The covering element can be in the form of, for example, a film of adhesive-coated polyimide (PI), polyethylene terephthalate (PET), polyester or other polymers. The covering element can additionally have a planar, dimensionally stable surface. The module having the covering element which is arranged above the components and the carrier substrate and has a planar, dimensionally stable surface therefore constitutes a space-saving and cost-effective way of placing the module at any point on a printed circuit board by means of a placement method by vacuum suction (pick-and-place method). Furthermore, the components which are arranged on the carrier substrate can be electromagnetically shielded by a conductive coating of the covering element and by mounting a conductive coupling element between the carrier substrate and the covering element.

A method for producing an electrical module for being received by automatic placement machines by means of generating a vacuum is specified below. The method comprises providing a carrier substrate. The carrier substrate is fitted with at least one component. A covering element is arranged above the at least one component by mounting the covering element on the at least one component by means of a fixing component.

Further embodiments of the module and of the method for producing a module can be found in the dependent claims.

The invention is explained in greater detail below with reference to figures which show exemplary embodiments of the present invention, and in which:

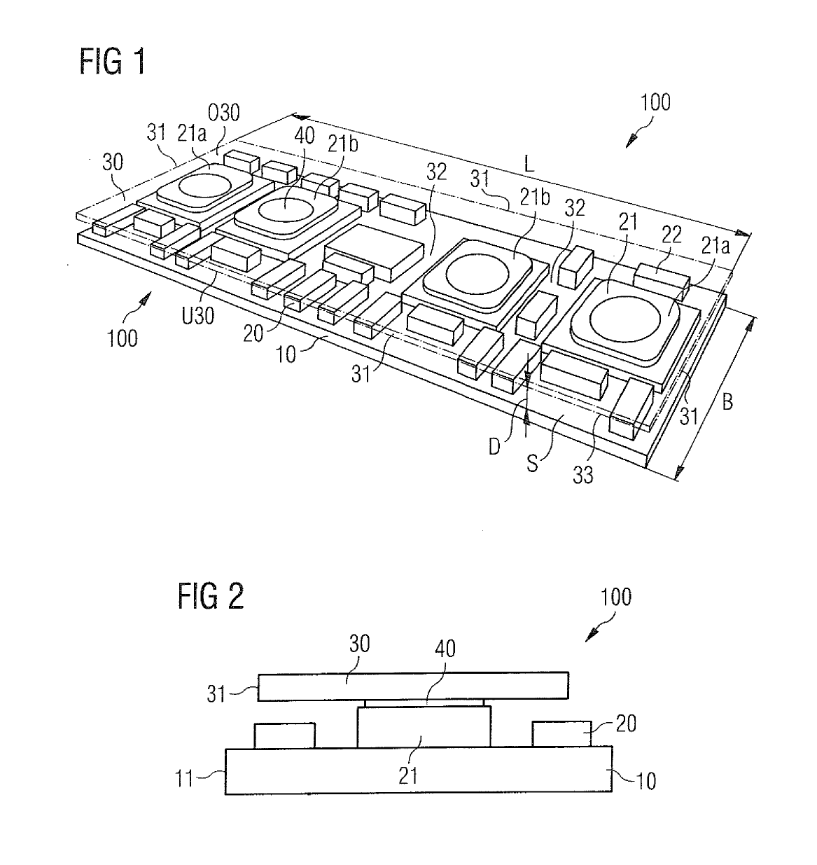

FIG. 1 shows an embodiment of an electrical module for being received by an automatic placement machine by means of generating a vacuum,

FIG. 2 shows a cross section through an embodiment of an electrical module for being received by an automatic placement machine by means of generating a vacuum,

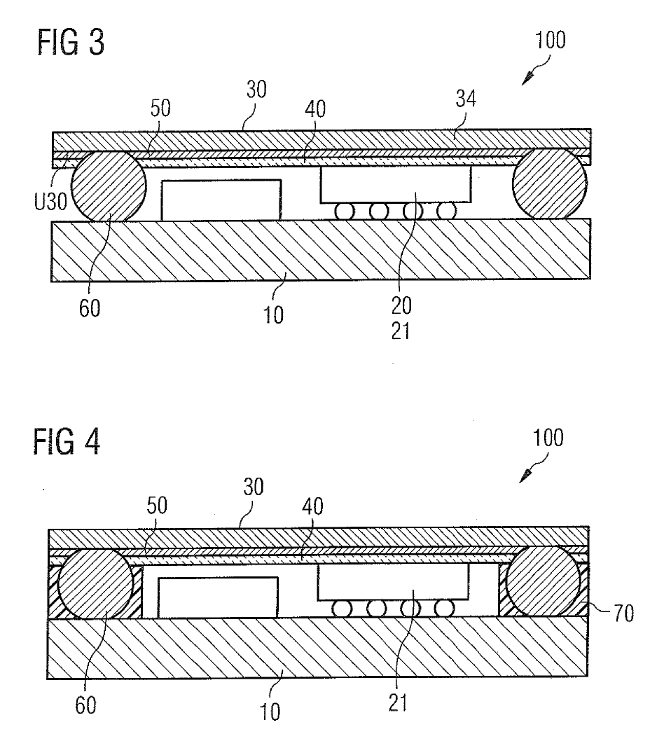

FIG. 3 shows a cross section through a further embodiment of an electrical module for being received by an automatic placement machine by means of generating a vacuum,

FIG. 4 shows a cross section through a further embodiment of an electrical module for being received by an automatic placement machine by means of generating a vacuum,

FIG. 5 shows a cross section through a further embodiment of an electrical module for being received by an automatic placement machine by means of generating a vacuum, and

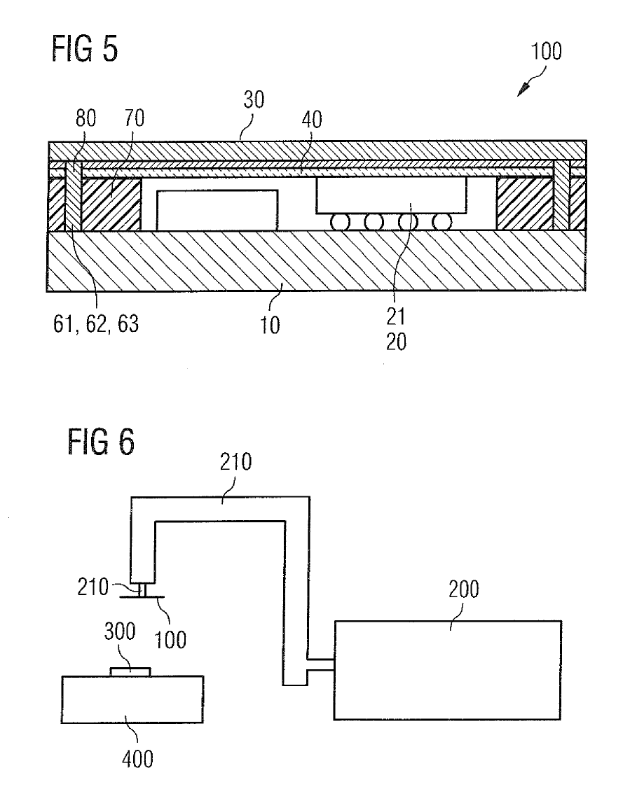

FIG. 6 shows an automatic placement machine for placing a module on a printed circuit board.

FIG. 1 shows an embodiment of an electrical module 100 with a length L and a width B. The module has a carrier substrate 10 on which a large number of components 20 are arranged. The components can be, for example, resistors, inductors, capacitors or surface acoustic wave components which are soldered onto the carrier substrate. The components can have a housing. A chip can be arranged in the housing. A covering element 30 is arranged above the carrier substrate 10 and the components 20. A fixing component 40 which is mounted on at least one of the components is provided for fastening the covering element above the components or the carrier substrate.

The components 20 can have different overall heights. Components 21 have, for example, a greater overall height than components 22. According to one possible embodiment, the fixing component 40 is preferably arranged on the components 21 which have the greatest overall height on the module. The fixing component can therefore be provided on one or more components. In particular, it is not necessary to mount the fixing component on all components of the module. Similarly, it is not necessary to mount the fixing component on all components 21 which have a greater overall height than other components. By way of example, the fixing component can be provided only on those components 21a which are arranged at the edge of the carrier substrate 10 or on the central components 21b which are arranged between the components at the edge.

In order to ensure that the components 21 on which the covering element 30 is fixed are securely held, the components 21 can additionally be fastened on the carrier substrate by means of the fixing component 40. To this end, the fixing component can be arranged not only on the upper face of the components 21 but also on the side faces of the components 21 and on the carrier substrate.

Besides applying the fixing component on the components, the covering element 30 can, as an alternative to this, be coated, on a lower face, with a fixing component 40. When the covering element and carrier substrate are joined to the components which are arranged thereon, the covering element is fixed to the highest components 21. The joining process can be performed, for example, by pressing the covering element onto the components.

The fixing component 40 can, for example, be in the form of an adhesive layer. The adhesive layer 40 can contain an epoxide or a silicone. Low height differences between the highest components 21 are compensated for by the adhesive in the adhesive-bonding process. The adhesive material used can be, for example, a 2-component resin system. The adhesive material cures at room temperature or at a higher temperature of between 100° C. and 150° C. The module can be heated to a temperature of this kind, for example, in an oven in which the module is heated. As a result, the covering element 30 is connected to the highest components 21. An air gap or a filling material can be arranged between the relatively low components 22 and the covering element 30.

In addition to an adhesive layer, a solder material can also be used as a fixing component, said solder material being applied to the components 21. The covering element 30 is fastened to the highest components 21 by melting the solder material at high temperatures and as a result of subsequent solidification of the solder material.

The carrier substrate 10 can be in the form of a laminate, in particular an epoxide-based laminate or a resin-based laminate. The epoxide-based laminate used can be, for example, an FR4 substrate. BT (bismaleimide triazine) substrates can also be used. The laminate has a plurality of thin layers which are compressed to form a stack. The carrier substrate can also have a material which is composed of a ceramic. The carrier substrate of the module can, for example, have a thickness of between 0.15 mm and 0.3 mm. A glass transition temperature of the material of the substrate can be approximately 180° C. A coefficient of thermal expansion of the substrate material can be approximately 17 ppm per Kelvin.

The covering element 30 is designed in such a way that it has a planar, dimensionally stable surface, and therefore a vacuum can be generated on the upper face O30 of the covering element by an automatic placement machine, as a result of which the module can adhere to a vacuum pipette of the automatic placement machine in a secure and reliable manner. Furthermore, the upper face O30 of the covering element can be designed in such a way that it can be labeled. A laser can be used for labeling, for example. The covering element can contain any material which is composed of a polymer, in particular of polyimide (PI), polyethylene terephthalate (PET) or polyester.

The covering element 30 and the carrier substrate 10 are preferably formed from the same material. A similar material to that used for the carrier substrate can also be used for the covering element. A material which has at least the same or similar thermomechanical properties as the material of the carrier substrate can be used for the covering element 30. By way of example, a material with a glass transition temperature of between 140° C. and 200° C. is used for the covering element 30. The coefficient of thermal expansion of the material of the covering element is preferably between 17 ppm per Kelvin and 25 ppm per Kelvin. The material of the covering element can have a modulus of elasticity of between 500 MPa and 650 MPa.

The covering element preferably has a thickness of between 10 μm and 150 μm. On account of the low thickness of the covering element, the module 100 has a flat shape. Since only an adhesive is applied to some of the components or the lower face of the covering element is coated with an adhesive layer in order to fix the covering element above the components and the carrier substrate, the covering element can be mounted in a highly cost-effective manner. The components 21 serve as carriers or supports for the covering element 30. Therefore, it is not necessary to provide the carrier substrate with regions which would be required for mounting supporting elements, and therefore no additional space is taken up on the carrier substrate.

In the embodiment of an electrical module which is shown in FIG. 1, the covering element 30 has an outer edge 31 and a remaining region 32. The outer edge surrounds the remaining region 32 of the covering element. The covering element 30 is designed in such a way that at least one section 33 of the covering element, which section comprises the outer edge 31 of the covering element, is arranged at a distance D from the carrier substrate 10. In contrast to a closed cover which is mounted on the carrier substrate, there is therefore an air gap S between the sections 33 of the edge of the covering element. The section 33 of the edge 31 of the covering element is therefore arranged at a distance from the carrier substrate by means of the air gap S. Since the covering element, in contrast to a cover, does not have any side elements which have to be fixed to the carrier substrate, the components 20 can be soldered onto the carrier substrate up to close to the saw track along which a module is separated from a populated carrier substrate surface (blank).

One advantage of a module of the embodiment shown in FIG. 1 over encapsulation of the components with an encapsulation material is that the stress which is exerted on the components and connections of the components by the encapsulation material in the event of temperature cycles is dispensed with. The reduced risk of short circuits between the components 20 in comparison to the method with encapsulation is also advantageous. Small cavities can be produced in the encapsulation material when the encapsulation material is applied. In the event of refusion (reflow) when fitting circuits with the modules, short circuits can occur at these points and lead to defects in the module. Since the fixing component is applied only on the components and therefore does not surround the components or flow beneath the components, short circuits of this kind cannot occur when a covering element is mounted above the components.

A method for producing the electrical module is specified below. A carrier substrate, for example a panel or a laminate, is initially provided. The carrier substrate 10 is fitted with components 20, wherein fitting is performed, for example, by means of SMD mounting. To this end, the components are mounted on designated regions of the carrier substrate which are coated with a solder paste. The solder material is melted under the action of temperature, for example a temperature of approximately 260° C., and the components 20 are fixed on the carrier substrate.

A fixing component 40, for example an adhesive material, is then applied on at least one of the components, preferably on the highest component 21. The fixing component can be applied on any of the components 21 which are higher than other components. However, the fixing component can also be arranged only on some of the highest components, for example on the components 21a which are placed at the edge of the carrier substrate or the components 21b which are placed on the carrier substrate centrally between the components 21a. The fixing component 40 can also be arranged in such a way that it can be arranged both on the outer face of the component and on the side faces of the components and on the carrier substrate. In this embodiment, the fixing component 40 in addition to fastening the covering element on the components, also allows the components to be securely fixed on the carrier substrate.

As an alternative to applying the adhesive to the highest components 21, the lower face U30 of the covering element can also be coated with the adhesive material 40. The covering element 30 is then mounted on the highest components 21. The adhesive cures at room temperature or during a heating process in an oven at a temperature of between 100° C. and 200° C. After the adhesive material has cured, the covering element 30 is fixed on the components 21.

A solder material can also be applied on the highest components 21 as the fixing component 40. The solder material is heated and melted. The solder material is then cooled down and solidified, as a result of which the covering element 30 is fixed on the highest components 21.

A large number of such modules can be produced in parallel on a relatively large carrier substrate surface, for example a carrier substrate surface of 100 mm×100 mm. The individual modules are separated from the fitted carrier substrate material (blank) by means of a sawing process. Sawing the blank into the individual modules can be performed by sawing by means of a saw blade, by water-jet sawing or by laser sawing. The sawing process can be executed as a single-stage process in which both the covering element and the carrier substrate are cut in one process step. In the case of a two-stage sawing process, the covering element is first cut out and then the carrier substrate is cut. After the modules are separated from the blank, the upper face O30 of the covering element of a module can be labeled in each case. Labeling can be performed, for example, by means of a laser beam.

FIG. 2 shows a cross section through an electrical module, in which the modules are separated from a blank by a two-stage sawing process. Therefore, the covering element 30 has a width which is slightly lower than the width of the carrier substrate. In the case of a single-stage sawing process, the edge 31 of the covering element 30 reaches as far as an edge 11 of the carrier substrate.

FIG. 3 shows an embodiment of an electrical module having a covering element 30 which is arranged above a substrate 10 and components 20. An adhesive layer is applied to a lower face U30 of the covering element 30, which lower face faces the carrier substrate 10, as the fixing component 40. By mounting and pressing the covering element 30 onto the components 20, the covering element can be firmly adhesively bonded and therefore fixed on the highest components 21 of the module. The covering element 30 has a planar, flat and dimensionally stable surface on the upper face O30, and therefore a vacuum can be generated by an automatic placement machine on the covering element, as a result of which the entire module can be held by the automatic placement machine.

The adhesive layer 40 can have an electrically insulating material. Therefore, the components do not come into electrical contact with the covering element. A covering element which is composed of a metal, which is at a floating potential, would otherwise act as an antenna and could interfere with the intended manner of operation of the components. If electromagnetic shielding of the components 20 is required, the lower face U30 of the covering element 30 can be coated with a conductive layer 50. The covering element 30 can be coated with a metal or with conductive particles, for example, on its lower face U30. The covering element can also contain a metallic material 34.

In order to provide shielding, the covering element 30 or the conductive layer 50 is electrically connected to the grounded carrier substrate 10 by a coupling element 60. Supports which are composed of a conductive material can be applied on the carrier substrate as coupling elements. The supports can be formed by a conductive adhesive which is applied, for example, in drops onto the carrier substrate. The coupling element can also be in the form of metallic supports (posts), for example as supports which are composed of copper. According to a further variant embodiment, the coupling elements 60 have a spherical design. In particular, the coupling elements can be in the form of solder balls.

Spherical coupling elements, for example solder balls, can be applied in a cost-effective manner by what is known as a gang ball placement method. In this case, a screen which has openings is arranged above the carrier substrate. The openings are filled with the spherical coupling elements. All coupling elements are then mounted on the carrier substrate and connected to the carrier substrate in a single manufacturing step. The connection can be made, for example, by a soldering process in which the spherical elements are soldered to the carrier substrate. The surface area required for this purpose is very low on account of the low bearing area of the solder balls.

After the spherical coupling elements are soldered onto the carrier substrate, the covering element can be quickly mounted by a subsequent reflow soldering process in which the coupling elements are soldered to the covering element. When the covering element and carrier substrate are joined, the coupling elements 60 are attached to the covering element 30. In this case, a pressure is applied to the covering element and the coupling elements in such a way that the electrically insulating adhesive layer 40 is pierced or displaced by plastic deformation. The coupling elements are preferably designed to be plastically deformable. On account of the plastic deformation of the solder balls 50 during mounting of the covering element, vertical adjustment of the covering element 30 is possible at the same time.

FIG. 4 shows a further embodiment of the module 100 in which electromagnetic shielding of the components 20 is achieved by means of the covering element 30. In contrast to the embodiment shown in FIG. 3, a layer 70 for fixing the coupling element between the covering element and the carrier substrate is formed at the edge of the carrier substrate 10 in the region of the sawing track, along which the module has been separated from a blank, and the coupling elements 60. The layer 70 can be applied to the carrier substrate, for example the fitted panel, as a wall (glob-top wall) by means of a screen-printing mask. The covering element 30 is applied to the still-soft wall 70, and therefore a closed space is produced around the components 20 on the carrier substrate. The material of the glob-top layer 70 is then cured.

In one embodiment, the coupling elements 60 are applied on the carrier substrate by an SMD process and fixed by means of the layer 70. After application of the covering element, the coupling elements 60 establish an electrical connection between the conductive material 34 of the covering element or the conductive layer 50 and the grounded carrier substrate 10.

In a further embodiment, no solder balls are used. In this case, the covering element can be formed from a metallizable plastic. According to the embodiment shown in FIG. 5, cavities 80, which can be made in the layer 70, are provided in the layer 70 for fixing the coupling elements. The recesses 80 can be made, for example, by laser drilling into the layer 70 of the wall. The drilled holes can extend through the covering element 30 and the layer 70. Electrical contact can then be made through the laser-drilled holes 80 by covering element and wall with subsequent electroplating of the covering element and the laser hole.

In order to establish an electrical connection between the conductive material 34 of the covering element 30 or the conductive layer 50 and the grounded carrier substrate 10, a conductive material can be inserted into the cavities 80, a coupling element 50 being formed between the covering element 30 and the carrier substrate 10 by said conductive material. The conductive material can be, for example, a conductive adhesive 61. As an alternative to this, a conductive coating 62 can be inserted into the cavities 80. A further way of establishing electrical contact between the covering element 30 and the grounded carrier substrate is the deposition of metals 63 in the holes 80.

The covering element 30 can also be in the form of a thin film with a thickness of between 10 μm and 150 μm in the embodiments shown in FIGS. 3, 4 and 5. Similarly to the embodiment shown in FIGS. 1 and 2, the film can contain, for example, an adhesive-coated polyimide (PI), polyethylene terephthalate (PET), polyester or other polymers, which are temperature-stable, in order to remain undamaged during a soldering process.

FIG. 6 shows an automatic placement machine 200 which places the module 100 on a printed circuit board 300 by means of vacuum pipettes 210. The printed circuit board 300 is mounted on a support 400. The module is sucked by the vacuum pipettes generating a vacuum on the surface of the planar, dimensionally stable covering element of the module, it being possible for the module to be securely held on an arm 220 of the automatic placement machine by means of said vacuum.

### LIST OF REFERENCE SYMBOLS

10 Carrier substrate
20 Components
30 Covering element
31 Edge of the covering element
32 Inner region of the covering element
33 Section of the covering element
34 Conductive material of the covering element
40 Fixing component
50 Conductive layer
60 Coupling element
70 Layer for fixing the coupling element
80 Cavity

1. An electrical module for being received by automatic placement machines by means of generating a vacuum, comprising:
a carrier substrate;
at least one component which is arranged on the carrier substrate; and
a covering element which is arranged above the at least one component,
wherein a fixing component, by means of which the covering element is fastened to the at least one component, is arranged between the covering element and the at least one component.

2. The electrical module according to claim 1, further comprising:
at least one further component which has a lower overall height than the at least one component,
wherein the fixing component is applied on the at least one component, and
wherein an air gap or a filling material is arranged between the at least one further component and the covering element.

3. The electrical module according to claim 1 or 2, wherein the covering element is arranged above the carrier substrate in such a way that a section of the covering element, which section comprises the outer edge of the covering element, is arranged at a distance from the carrier substrate by an air gap.

4. The electrical module according to claim 1, wherein the fixing component is in the form of an adhesive layer, in particular in the form of an adhesive layer which is composed of an epoxide or a silicone.

5. The electrical module according to claim 1, wherein the fixing component has an electrically insulating material.

6. The electrical module according to claim 1, wherein the covering element has a conductive material.

7. The electrical module according to claim 1,
wherein the covering element is coated with a conductive material on a side which faces the carrier substrate, and
wherein the conductive material is arranged between the adhesive layer and the covering element.

8. The electrical module according to claim 6 or 7, further comprising:
a coupling element for establishing electrical coupling between the conductive material and the carrier substrate,
wherein the coupling element is arranged on the carrier substrate.

9. The electrical module according to claim 8, comprising:
a layer for fixing the coupling element between the carrier element and the covering element,
wherein the layer for fixing the coupling element contains a material which has a higher resistance than the material of the coupling element, and
wherein the layer for fixing the coupling element is arranged on the carrier substrate.

10. The electrical module according to claim 8, wherein the coupling element has a conductive adhesive or a conductive coating or a material which is composed of metal.

11. A method for producing an electrical module for being received by automatic placement machines by means of generating a vacuum, comprising:
providing a carrier substrate;
fitting the carrier substrate with at least one component; and
arranging a covering element above the at least one component by fastening the covering element on the at least one component by means of a fixing component.

12. The method according to claim 11, further comprising:
fitting the carrier substrate with at least one further component, wherein the at least one further component has a lower overall height than the at least one component; and
applying the fixing component, in particular an adhesive layer, on the at least one component.

13. The method according to claim 11, further comprising:
applying an adhesive layer on a side of the covering element, which side faces the carrier substrate after the step of arranging the covering element above the at least one component.

14. The method according to one of claims 11 to 13, further comprising:
coating a side of the covering element, which side faces the carrier substrate after the step of arranging the covering element above the at least one component, with a conductive material;
arranging a coupling element on the carrier substrate in order to establish electrical coupling between the conductive material and the carrier substrate; and
pressing the covering element on the coupling element in such a way that the coupling element displaces the fixing component at one point and the conductive material makes contact with the coupling element at said point.

15. The method according to claim 14, further comprising:
applying a layer for fixing the coupling element between the carrier substrate and the covering element on the carrier substrate;
making a cavity in the layer for fixing the coupling element; and
inserting the coupling element into the cavity.
